(19) United States
(12) Patent Application Publication
(10) Pub. No.: US 2026/0156919 A1
(43) Pub. Date: Jun. 4, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventor: Kazutoshi NAKAMURA, Nonoichi Ishikawa (JP)

(21) Appl. No.: 19/369,796

(22) Filed: Oct. 27, 2025

(30) Foreign Application Priority Data
Dec. 3, 2024 (JP) 2024-209871

(51) Int. Cl. H10D 84/00; H10D 84/01

(52) U.S. Cl. CPC H10D 84/161; H10D 84/0109

(57) ABSTRACT

A semiconductor device of an embodiment includes transistor region and diode region. The semiconductor device includes semiconductor layer including: first conductivity type first semiconductor region; second conductivity type second semiconductor region between the first semiconductor region and first face; third semiconductor region between the second semiconductor region and the first face and having second conductivity type impurity concentration lower than the second semiconductor region; and sixth semiconductor region between the second semiconductor region and second face and having second conductivity type impurity concentration higher than the second semiconductor region, the second semiconductor region includes first region between the sixth semiconductor region and the third semiconductor region and second region between the first semiconductor region and the third semiconductor region, second conductivity type impurity concentration of the first region is 80% to 120% of the second region, and carrier concentration of the first region is lower than the second region.

### CROSS-REFERENCE TO RELATED APPLICATION

This application is based upon and claims the benefit of priority from Japanese Patent Application No. 2024-209871, filed on Dec. 3, 2024, the entire contents of which are incorporated herein by reference.

### FIELD

Embodiments described herein relate generally to a semiconductor device.

### BACKGROUND

An insulated gate bipolar transistor (IGBT) is one example of a power semiconductor device. In the IGBT, for example, a p-type collector region, an n-type drift region, and a p-type base region are provided on a collector electrode. A gate electrode is provided in a trench penetrating through the p-type base region and reaching the n-type drift region, with a gate insulating film interposed between the gate electrode and the trench. An n-type emitter region connected to an emitter electrode is provided in a region adjacent to the trench on the surface of the p-type base region.

In recent years, a reverse-conducting IGBT (RC-IGBT) in which an IGBT and a free wheeling diode are formed in the same semiconductor chip has been widely developed and commercialized. The RC-IGBT is used, for example, as a switching element in an inverter circuit. The free wheeling diode has a function of making a current flow in a direction opposite to the on-current of the IGBT. Forming the IGBT and the free wheeling diode in the same semiconductor chip has many advantages, such as simplification of assembly and dispersion of heat generation locations.

### BRIEF DESCRIPTION OF THE DRAWINGS

FIG. 1 is a schematic diagram of a semiconductor device of a first embodiment;

FIG. 2 is a schematic cross-sectional view of a part of the semiconductor device of the first embodiment;

FIG. 3 is a schematic cross-sectional view illustrating an example of a method for manufacturing the semiconductor device of the first embodiment;

FIG. 4 is a schematic cross-sectional view illustrating an example of the method for manufacturing the semiconductor device of the first embodiment;

FIG. 5 is a schematic cross-sectional view illustrating an example of the method for manufacturing the semiconductor device of the first embodiment;

FIG. 6 is a schematic cross-sectional view illustrating an example of the method for manufacturing the semiconductor device of the first embodiment;

FIG. 7 is a schematic cross-sectional view illustrating an example of a method for manufacturing the semiconductor device of the first embodiment;

FIG. 8 is a schematic cross-sectional view illustrating an example of the method for manufacturing the semiconductor device of the first embodiment;

FIG. 9 is a schematic cross-sectional view of a part of a semiconductor device of a second embodiment;

FIG. 10 is a schematic cross-sectional view illustrating an example of a method for manufacturing the semiconductor device of the second embodiment;

FIG. 11 is an explanatory diagram of the function of the semiconductor device of the second embodiment;

FIG. 12 is an explanatory diagram of the function and effect of the semiconductor device of the second embodiment;

FIG. 13 is a schematic cross-sectional view of a part of a semiconductor device of a modification of the second embodiment;

FIG. 14 is a schematic cross-sectional view of a part of a semiconductor device of a third embodiment; and

FIG. 15 is a schematic cross-sectional view of a part of a semiconductor device of a modification of the third embodiment.

### DETAILED DESCRIPTION

A semiconductor device of an embodiment includes: a transistor region; and a diode region, in which the transistor region includes: a semiconductor layer having a first face and a second face opposed to the first face, the semiconductor layer including a first semiconductor region of a first conductivity type in contact with the second face, a second semiconductor region of a second conductivity type provided between the first semiconductor region and the first face, a third semiconductor region of the second conductivity type provided between the second semiconductor region and the first face and having a second conductivity type impurity concentration lower than a second conductivity type impurity concentration of the second semiconductor region, a fourth semiconductor region of the first conductivity type provided between the third semiconductor region and the first face, and a fifth semiconductor region of the second conductivity type provided between the fourth semiconductor region and the first face and in contact with the first face; a gate electrode opposed to the fourth semiconductor region; a gate insulating film provided between the gate electrode and the fourth semiconductor region; a first electrode in contact with the fifth semiconductor region; and a second electrode in contact with the first semiconductor region, the diode region includes: the semiconductor layer including the second semiconductor region, the third semiconductor region, a sixth semiconductor region of the second conductivity type provided between the second semiconductor region and the second face, in contact with the second face, and having a second conductivity type impurity concentration higher than the second conductivity type impurity concentration of the second semiconductor region, and a seventh semiconductor region of the first conductivity type provided between the third semiconductor region and the first face and in contact with the first face; the first electrode in contact with the seventh semiconductor region; and the second electrode in contact with the sixth semiconductor region, the second semiconductor region includes a first region and a second region, the first region is provided between the sixth semiconductor region and the third semiconductor region, the second region is provided between the first semiconductor region and the third semiconductor region, and a second conductivity type impurity concentration of the first region is equal to or more than 80% and equal to or less than 120% of a second conductivity type impurity concentration of the second region, and a carrier concentration of the first region is lower than a carrier concentration of the second region.

Hereinafter, embodiments of this disclosure will be described with reference to the drawings. Note that, in the following description, the same or similar members and the like are denoted by the same reference numerals, and the description of the members and the like once described will be omitted as appropriate.

In this specification, when there are notations of n⁺-type, n-type, and n⁻-type, it means that an n-type impurity concentration decreases in the order of n⁺-type, n-type, and n⁻-type. When there are notations of p⁺-type, p-type, and p⁻-type, it means that a p-type impurity concentration decreases in the order of p⁺-type, p-type, and p⁻-type.

In this specification, the n-type impurity concentration does not indicate an actual n-type impurity concentration, but indicates an effective n-type impurity concentration after compensation. Similarly, the p-type impurity concentration does not indicate an actual p-type impurity concentration, but indicates an effective p-type impurity concentration after compensation. For example, when the actual n-type impurity concentration is higher than the actual p-type impurity concentration, the concentration obtained by subtracting the p-type impurity concentration from the actual n-type impurity concentration is defined as the n-type impurity concentration. The same applies to the p-type impurity concentration.

In this specification, the n-type impurity concentration and the p-type impurity concentration are not the concentration of activated impurities but the atomic concentration of physically existing impurity atoms.

In this specification, the carrier concentration means the concentration of activated impurities.

The distribution and absolute value of the impurity concentration of a semiconductor region can be measured using, for example, secondary ion mass spectrometry (SIMS) or energy dispersive X-ray spectroscopy (EDX).

The relative magnitude relationship and absolute value of the carrier concentration of the semiconductor region can be measured using, for example, scanning capacitance microscopy (SCM) or spreading resistance analysis (SRA).

For example, the planar distribution of the semiconductor region can be evaluated using the SCM. For example, a depth of the semiconductor region and a distance between the semiconductor regions can be measured using the SCM.

The impurity concentration or the carrier concentration of the semiconductor region is represented by the impurity concentration or the carrier concentration in the vicinity of the center of the semiconductor region unless otherwise specified in the specification.

The relative magnitude relationship of the crystal defect density of the semiconductor region can be measured using, for example, transmission electron microscopy (TEM) or photo luminescence (PL).

### First Embodiment

A semiconductor device of a first embodiment includes a transistor region and a diode region. The transistor region includes: a semiconductor layer having a first face and a second face opposed to the first face, the semiconductor layer including a first semiconductor region of a first conductivity type in contact with the second face, a second semiconductor region of a second conductivity type provided between the first semiconductor region and the first face, a third semiconductor region of the second conductivity type provided between the second semiconductor region and the first face and having a second conductivity type impurity concentration lower than a second conductivity type impurity concentration of the second semiconductor region, a fourth semiconductor region of the first conductivity type provided between the third semiconductor region and the first face, and a fifth semiconductor region of a second conductivity type provided between the fourth semiconductor region and the first face and in contact with the first face; a gate electrode opposed to the fourth semiconductor region; a gate insulating film provided between the gate electrode and the fourth semiconductor region; a first electrode in contact with the fifth semiconductor region; and a second electrode in contact with the first semiconductor region. The diode region includes: the semiconductor layer including the second semiconductor region, the third semiconductor region, a sixth semiconductor region of the second conductivity type provided between the second semiconductor region and the second face, in contact with the second face, and having a second conductivity type impurity concentration higher than the second conductivity type impurity concentration of the second semiconductor region, and a seventh semiconductor region of the first conductivity type provided between the third semiconductor region and the first face and in contact with the first face; the first electrode in contact with the seventh semiconductor region; and the second electrode in contact with the sixth semiconductor region. The second semiconductor region includes a first region and a second region, the first region is provided between the sixth semiconductor region and the third semiconductor region, the second region is provided between the first semiconductor region and the third semiconductor region. A second conductivity type impurity concentration of the first region is equal to or more than 80% and equal to or less than 120% of a second conductivity type impurity concentration of the second region, and a carrier concentration of the first region is lower than a carrier concentration of the second region.

The semiconductor device of the first embodiment is an RC-IGBT 100 in which an IGBT and a free wheeling diode are formed on the same semiconductor chip. The RC-IGBT 100 includes a trench-gate type IGBT including a gate electrode in a trench formed in a semiconductor layer. Hereinafter, a case where a first conductivity type is p-type and a second conductivity type is n-type will be described as an example.

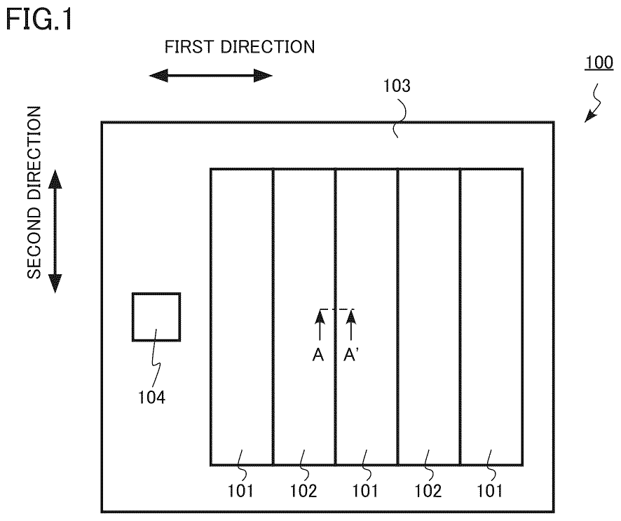

FIG. 1 is a schematic diagram of a semiconductor device of a first embodiment.

As illustrated in FIG. 1, the RC-IGBT 100 includes a transistor region 101, a diode region 102, and a termination region 103. The transistor region 101 and the diode region 102 are alternately disposed in a first direction. The transistor region 101 and the diode region 102 extend in a second direction perpendicular to the first direction. The termination region 103 surrounds the transistor region 101 and the diode region 102.

The transistor region 101 operates as the IGBT. The diode region 102 operates as the free wheeling diode. The free wheeling diode is, for example, a fast recovery diode (FRD).

The termination region 103 lessens the intensity of the electric field applied to the termination portion of the pn junction in the transistor region 101 and the diode region 102 when the RC-IGBT 100 is in an off-state. The termination region 103 has a function of improving breakdown voltage characteristics of the RC-IGBT 100.

A gate electrode pad 104 is provided in the termination region 103.

The RC-IGBT 100 of the first embodiment includes a semiconductor layer 10, an upper electrode 12 (first electrode), a lower electrode 14 (second electrode), a gate insulating film 41, a dummy gate insulating film 42, a gate electrode 51, a dummy gate electrode 52, an interlayer insulating layer 60, and a gate electrode pad 104. The dummy gate electrode 52 is connected to the emitter electrode, and does not form an inversion layer in a p-type anode region 38.

The semiconductor layer 10 includes gate trenches 21, dummy trenches 22, a p-type collector region 26 (first semiconductor region), an n-type first buffer region 28 (second semiconductor region), an n⁻-type drift region 30 (third semiconductor region), a p-type base region 32 (fourth semiconductor region), an n⁺-type emitter region 34 (fifth semiconductor region), an n⁺-type contact region 36 (sixth semiconductor region), and a p-type anode region 38 (seventh semiconductor region). The first buffer region 28 includes a first region 28a and a second region 28b.

The semiconductor layer 10 has a first face F1 and a second face F2 opposed to the first face F1. The semiconductor layer 10 is, for example, single crystal silicon. The thickness of the semiconductor layer 10 is, for example, equal to or more than 40 μm and equal to or less than 700 μm.

In this specification, a direction parallel to the first face F1 is referred to as a first direction. A direction parallel to the first face F1 and perpendicular to the first direction is referred to as a second direction. A direction connecting the first face F1 and the second face F2 is referred to as a third direction.

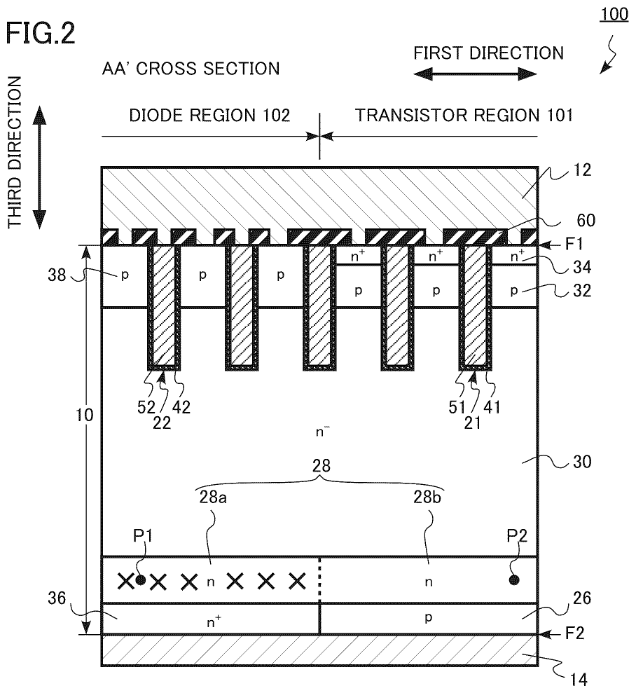

FIG. 2 is a schematic cross-sectional view of a part of the semiconductor device of the first embodiment. FIG. 2 is a schematic cross-sectional view of a boundary portion between the diode region 102 and the transistor region 101. FIG. 2 is an AA′ cross section of FIG. 1.

The transistor region 101 includes the semiconductor layer 10, the upper electrode 12 (first electrode), the lower electrode 14 (second electrode), the gate insulating film 41, the gate electrode 51, and the interlayer insulating layer 60.

The semiconductor layer 10 of the transistor region 101 includes the gate trenches 21, the p-type collector region 26 (first semiconductor region), the n⁻-type drift region 30 (third semiconductor region), the p-type base region 32 (fourth semiconductor region), and the n⁺-type emitter region 34 (fifth semiconductor region).

The upper electrode 12 is provided on a side of the first face F1 of the semiconductor layer 10. At least a part of the upper electrode 12 is in contact with the first face F1 of the semiconductor layer 10.

The upper electrode 12 functions as an emitter electrode of the IGBT in the transistor region 101. The upper electrode 12 is, for example, metal.

The upper electrode 12 is in contact with the emitter region 34. The upper electrode 12 is electrically connected to the emitter region 34.

The lower electrode 14 is provided on a side of the second face F2 of the semiconductor layer 10. The lower electrode 14 is in contact with the second face F2 of the semiconductor layer 10.

The lower electrode 14 functions as a collector electrode of the IGBT in the transistor region 101. The lower electrode 14 is, for example, metal.

The lower electrode 14 is in contact with the collector region 26 in the transistor region 101. The lower electrode 14 is electrically connected to the collector region 26 in the transistor region 101.

The collector region 26 is a p-type semiconductor region. The collector region 26 is in contact with the second face F2. The collector region 26 is electrically connected to the lower electrode 14. The collector region 26 is in contact with the lower electrode 14. The collector region 26 is a hole supply source when the IGBT is in an on-state.

The first buffer region 28 is an n-type semiconductor region. The first buffer region 28 is provided between the collector region 26 and the first face F1. The second region 28b of the first buffer region 28 is provided between the collector region 26 and the first face F1.

The first buffer region 28 has a function of suppressing the extension of the depletion layer extending from the side of the first face F1 when the IGBT is in an off-state and maintaining the breakdown voltage of the IGBT.

The drift region 30 is an n⁻-type semiconductor region. The drift region 30 is provided between the first buffer region 28 and the first face F1. The n-type impurity concentration of the drift region 30 is lower than the n-type impurity concentration of the first buffer region 28.

The drift region 30 is a path of an on-current when the IGBT is in an on-state. The drift region 30 is depleted when the IGBT is in an off-state, and has a function of maintaining a breakdown voltage of the IGBT.

The base region 32 is a p-type semiconductor region. The base region 32 is provided between the drift region 30 and the first face F1.

In a region of the base region 32 opposed to the gate electrode 51, an n-type inversion layer is formed when the IGBT is in an on-state. The base region 32 functions as a channel region of a transistor.

The emitter region 34 is an n⁺-type semiconductor region. The emitter region 34 is provided between the base region 32 and the first face F1. The emitter region 34 is in contact with the first face F1.

The n-type impurity concentration of the emitter region 34 is higher than the n-type impurity concentration of the drift region 30.

The emitter region 34 is in contact with the upper electrode 12. The emitter region 34 is electrically connected to the upper electrode 12. The emitter region 34 is an electron-supply source when a transistor is in an on-state.

The gate trenches 21 are provided on a side of the first face F1 of the semiconductor layer 10. The gate trenches 21 are grooves provided in the semiconductor layer 10. The gate trenches 21 are a part of the semiconductor layer 10.

The gate electrode 51 is provided in the gate trench 21. The gate electrode 51 is, for example, a semiconductor or metal. The gate electrode 51 is, for example, amorphous silicon or polycrystalline silicon, which contains the n-type impurity or the p-type impurity.

The gate electrode 51 is electrically connected to the gate electrode pad 104.

The gate insulating film 41 is provided between the gate electrode 51 and the semiconductor layer 10. The gate insulating film 41 is provided between the gate electrode 51 and the base region 32. The gate insulating film 41 is, for example, silicon oxide.

The interlayer insulating layer 60 is provided between the gate electrode 51 and the upper electrode 12. The interlayer insulating layer 60 electrically isolates the gate electrode 51 from the upper electrode 12. The interlayer insulating layer 60 is, for example, silicon oxide.

The diode region 102 includes the semiconductor layer 10, the upper electrode 12 (first electrode), the lower electrode 14 (second electrode), the dummy gate insulating film 42, the dummy gate electrode 52, and the interlayer insulating layer 60.

The semiconductor layer 10 of the diode region 102 includes the dummy trenches 22, the n⁺-type contact region 36 (sixth semiconductor region), the n-type first buffer region 28 (second semiconductor region), the n⁻-type drift region 30 (third semiconductor region), and the p-type anode region 38 (seventh semiconductor region).

The upper electrode 12 functions as an anode electrode of a diode in the diode region 102. The upper electrode 12 is in contact with the anode region 38.

The lower electrode 14 functions as a cathode electrode of a diode in the diode region 102. The lower electrode 14 is in contact with the contact region 36.

The contact region 36 is an n⁺-type semiconductor region. The contact region 36 is in contact with the second face F2. The contact region 36 is an electron-supply source when the diode is in an on-state. The contact region 36 is in contact with the lower electrode 14.

The first buffer region 28 is an n-type semiconductor region. The first buffer region 28 is provided between the contact region 36 and the first face F1. The first region 28a of the first buffer region 28 is provided between the contact region 36 and the first face F1.

The drift region 30 is an n⁻-type semiconductor region. The drift region 30 is provided between the first buffer region 28 and the first face F1.

The drift region 30 is a path of an on-current when the diode is in an on-state.

The anode region 38 is a p-type semiconductor region. The anode region 38 is provided between the drift region 30 and the first face F1.

The anode region 38 is a hole supply source when the diode is in an on-state.

The anode region 38 is in contact with the upper electrode 12. The anode region 38 is electrically connected to the upper electrode 12.

The dummy trenches 22 are provided on a side of the first face F1 of the semiconductor layer 10. The dummy trenches 22 are grooves provided in the semiconductor layer 10. The dummy trenches 22 are a part of the semiconductor layer 10.

The dummy gate electrode 52 is provided in the dummy trench 22. The dummy gate electrode 52 is, for example, a semiconductor or metal. The dummy gate electrode 52 is, for example, amorphous silicon or polycrystalline silicon, which contains the n-type impurity or the p-type impurity.

The dummy gate electrode 52 is electrically connected, for example, to the upper electrode 12.

The dummy gate insulating film 42 is provided between the dummy gate electrode 52 and the semiconductor layer 10.

The first buffer region 28 includes a first region 28a and a second region 28b.

The first region 28a is provided between the contact region 36 and the drift region 30. The first region 28a is in contact with the contact region 36 and the drift region 30. The first region 28a is provided directly above the contact region 36. The first region 28a is provided in the third direction of the contact region 36.

The second region 28b is provided between the collector region 26 and the drift region 30. The second region 28b is in contact with the collector region 26 and the drift region 30. The second region 28b is provided directly above the collector region 26. The second region 28b is provided in the third direction of the collector region 26.

The n-type impurity concentration of the first region 28 a is equal to or more than 80% and equal to or less than 120% of the n-type impurity concentration of the second region 28b. The n-type impurity concentration of the first region 28a is, for example, equal to or more than 90% and equal to or less than 110% of the n-type impurity concentration of the second region 28b. The n-type impurity concentration of the first region 28a is, for example, substantially the same as the n-type impurity concentration of the second region 28b.

The carrier concentration of the first region 28a is lower than the carrier concentration of the second region 28b. The carrier concentration of the first region 28 a is, for example, equal to or more than 1/1000 and equal to or less than ½ of the carrier concentration of the second region 28b.

The n-type impurity concentration and the carrier concentration of the first region 28a are measured, for example, at a position of a first point P1 in FIG. 2. The n-type impurity concentration and the carrier concentration of the second region 28b are measured, for example, at a position of a second point P2 in FIG. 2. A distance in the third direction from the second face F2 to the first point P1 is equal to a distance in the third direction from the second face F2 to the second point P2.

The first region 28a includes crystal defects. The crystal defects included in the first region 28a function as lifetime killers. When the crystal defects included in the first region 28a function as lifetime killers, for example, the switching characteristics of the free wheeling diode are improved.

The second region 28b includes or does not include crystal defects. The crystal defect density of the second region 28b is, for example, lower than the crystal defect density of the first region 28a. The crystal defect density of the first region 28a is, for example, higher than the crystal defect density of the second region 28b.

Next, an example of a method for manufacturing the semiconductor device of the first embodiment will be described.

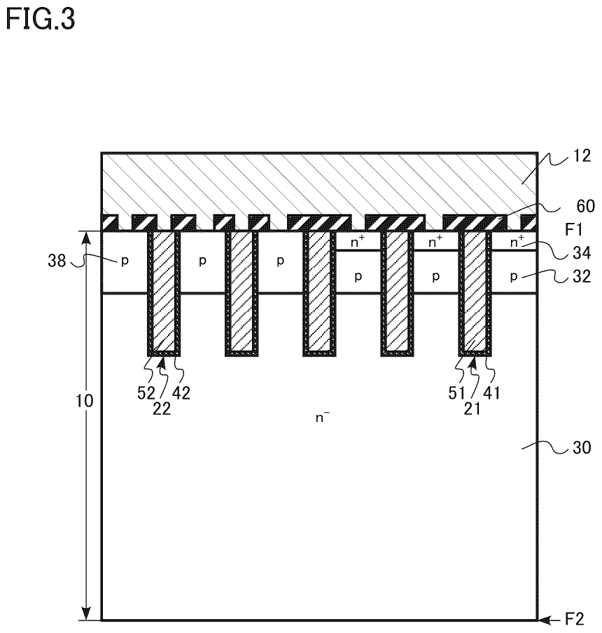

FIGS. 3, 4, 5, 6, 7, and 8 are schematic cross-sectional views illustrating an example of the method for manufacturing the semiconductor device of the first embodiment. FIGS. 3 to 8 are views corresponding to FIG. 2.

First, the gate trench 21, the dummy trench 22, the p-type base region 32, the n⁺-type emitter region 34, the p-type anode region 38, the gate insulating film 41, the dummy gate insulating film 42, the gate electrode 51, the dummy gate electrode 52, the interlayer insulating layer 60, and the upper electrode 12 are formed on a side of the first face F1 of the semiconductor layer 10 including the n⁻-type drift region 30 by using a known process technique (FIG. 3).

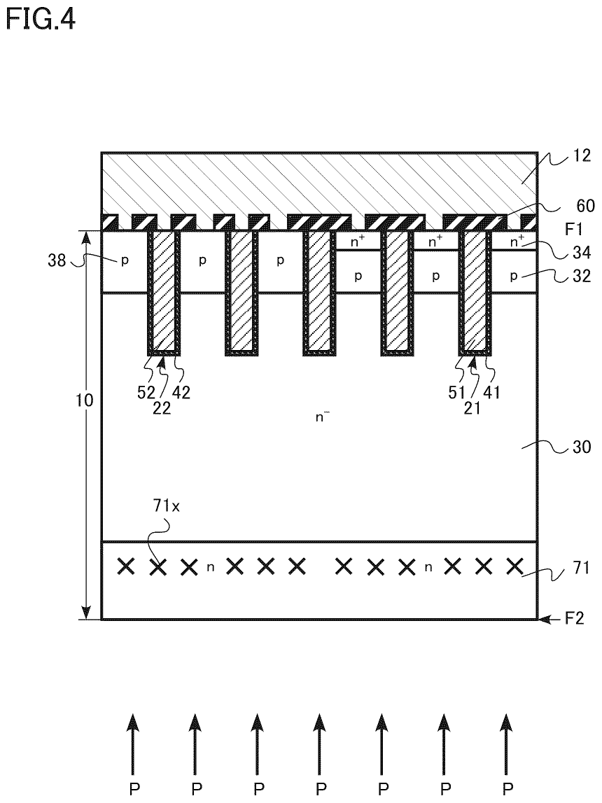

Next, first ion implantation is performed. In the first ion implantation, n-type impurities are implanted into the semiconductor layer 10 from a side of the second face F2 by using an ion implantation method (FIG. 4). The n-type impurities are, for example, phosphorus (P). A first n-type region 71 is formed by implantation of n-type impurities. A part of the first n-type region 71 finally becomes the first buffer region 28. Crystal defects 71x associated with ion implantation are formed in the first n-type region 71.

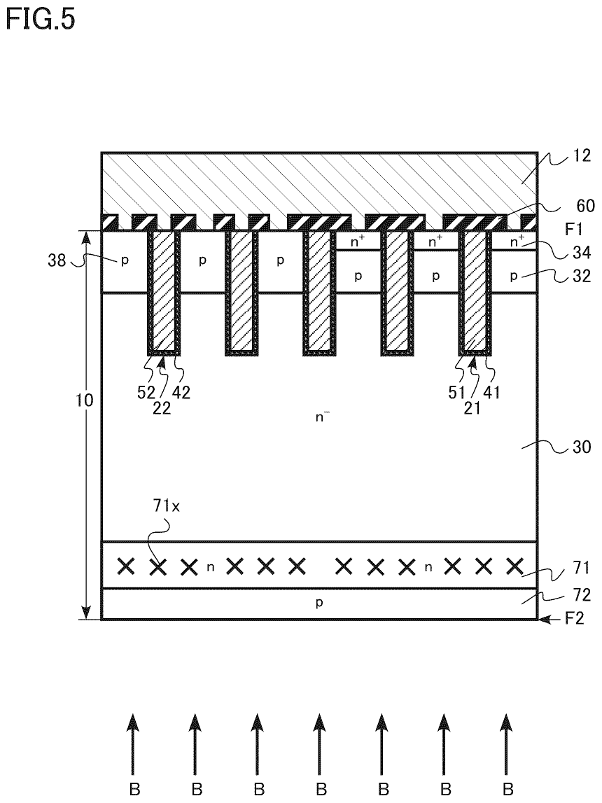

Next, second ion implantation is performed. In the second ion implantation, p-type impurities are implanted into the semiconductor layer 10 from a side of the second face F2 by using an ion implantation method (FIG. 5). The p-type impurities are, for example, boron (B). A p-type region 72 is formed between the first n-type region 71 and the second face F2 by implantation of p-type impurities. A part of the p-type region 72 finally becomes the collector region 26.

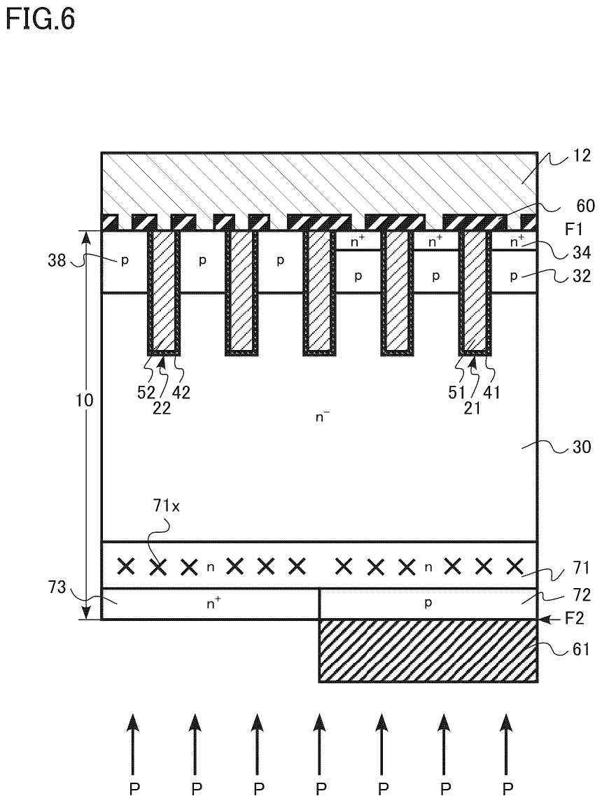

Next, a resist layer 61 is formed on a part of the second face F2. Next, third ion implantation is performed. In the third ion implantation, n-type impurities are implanted into the semiconductor layer 10 from a side of the second face F2 using the resist layer 61 as a mask by using an ion implantation method (FIG. 6). The dose amount of the n-type impurities of the third ion implantation is higher than the dose amount of the n-type impurities of the first ion implantation. The n-type impurities are, for example, phosphorus (P). A second n-type region 73 is formed by implantation of n-type impurities. A part of the second n-type region 73 finally becomes the contact region 36. The second n-type region 73 is brought into an amorphous state by ion implantation with a high dose amount.

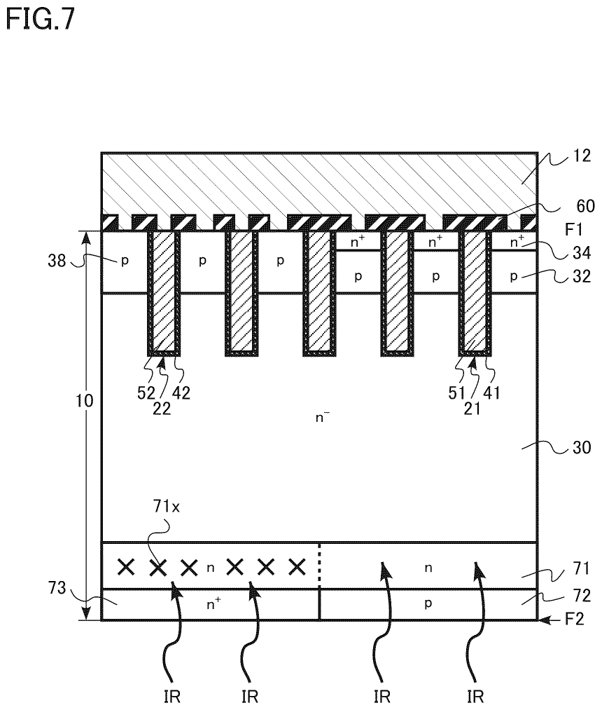

Next, the resist layer 61 is removed. Next, the semiconductor layer 10 is irradiated with infrared laser IR from a side of the second face F2 (FIG. 7). By using the infrared laser IR having a long wavelength, the laser light can reach a position away from the second face F2.

Irradiation with the infrared laser IR activates n-type impurities in the first n-type region 71 directly above the p-type region 72. The crystal defects, which have formed in the first n-type region 71 directly above the p-type region 72, formed according to the ion implantation are recovered and disappear.

On the other hand, activation of n-type impurities in the first n-type region 71 directly above the second n-type region 73 is suppressed. The recovery and disappearance of crystal defects formed in the first n-type region 71 directly above the second n-type region 73 are suppressed. This is because the infrared laser IR with which the second n-type region 73 is irradiated is absorbed by the second n-type region 73 in an amorphous state, and is prevented from reaching the first n-type region 71.

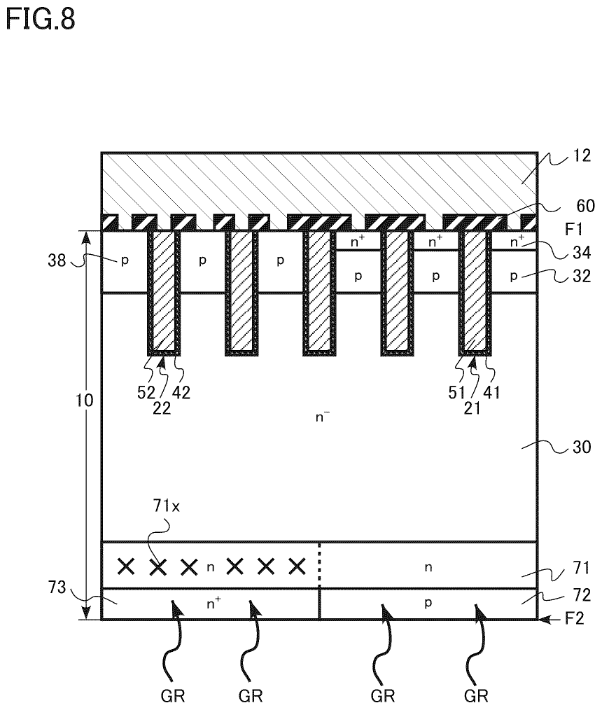

Next, the semiconductor layer 10 is irradiated with green laser GR from a side of the second face F2 (FIG. 8). By using the green laser GR having a wavelength shorter than the wavelength of the infrared laser IR, the vicinity of the second face F2 is effectively irradiated with the laser light. Since the green laser GR has a short wavelength, it is difficult for the green laser GR to reach a position away from the second face F2.

Irradiation with the green laser GR activates p-type impurities in the p-type region 72 and n-type impurities in the second n-type region 73.

The RC-IGBT 100 of the first embodiment illustrated in FIG. 2 can be manufactured by the above manufacturing method.

Next, the function and effect of the semiconductor device of the first embodiment will be described.

In the RC-IGBT, in order to improve the switching characteristics of the free wheeling diode, lifetime control may be performed by introducing a lifetime killer. On the other hand, when the lifetime control is performed, leakage current at a high temperature increases, the RC-IGBT may undergo thermal runaway, and the RC-IGBT may be destroyed.

In the RC-IGBT 100 of the first embodiment, a lifetime killer is introduced only into the first buffer region 28 of the diode region 102. That is, a lifetime killer is introduced only into the first region 28a which is the first buffer region 28 of the diode region 102.

A lifetime killer is not introduced into the first buffer region 28 of the transistor region 101. That is, a lifetime killer is not introduced into the second region 28b which is the first buffer region 28 of the transistor region 101.

Therefore, in the transistor region 101, defects are sufficiently reduced as compared with the first region 28a, so that leakage current at a high temperature does not become a problem. Therefore, according to the RC-IGBT 100 of the first embodiment, thermal runaway at a high temperature is suppressed as compared with a structure in which a lifetime killer is introduced into both the transistor region and the diode region.

In particular, as described above, in the RC-IGBT 100 of the first embodiment, the infrared laser IR and the green laser GR are used to activate impurities, and a lifetime killer can be formed in a self-aligned manner only directly above the contact region 36 of the diode region 102. In other words, a lifetime killer can be formed in a self-aligned manner at a boundary between the diode region 102 and the transistor region 101. According to the RC-IGBT 100 of the first embodiment, an RC-IGBT with suppressed thermal runaway at a high temperature can be manufactured by a simple process.

From the viewpoint of increasing the crystal defect density and effectively performing the lifetime control, the carrier concentration of the first region 28a is preferably equal to or less than ½, more preferably equal to or less than ⅕, and still more preferably equal to or less than 1/10 of the carrier concentration of the second region 28b.

As described above, according to the first embodiment, a semiconductor device including an RC-IGBT having an IGBT and a diode and capable of improving characteristics by suppressing thermal runaway at a high temperature can be realized.

### Second Embodiment

A semiconductor device of a second embodiment is different from the semiconductor device of the first embodiment in that the second semiconductor region further includes a third region, and the third region is in contact with the second face, the third region is provided between the sixth semiconductor region and the first semiconductor region, and the carrier concentration of the first region is lower than a carrier concentration of the third region. Hereinafter, description of contents overlapping with the first embodiment may be partially omitted.

The semiconductor device of the second embodiment is an RC-IGBT 200 in which an IGBT and a free wheeling diode are formed on the same semiconductor chip.

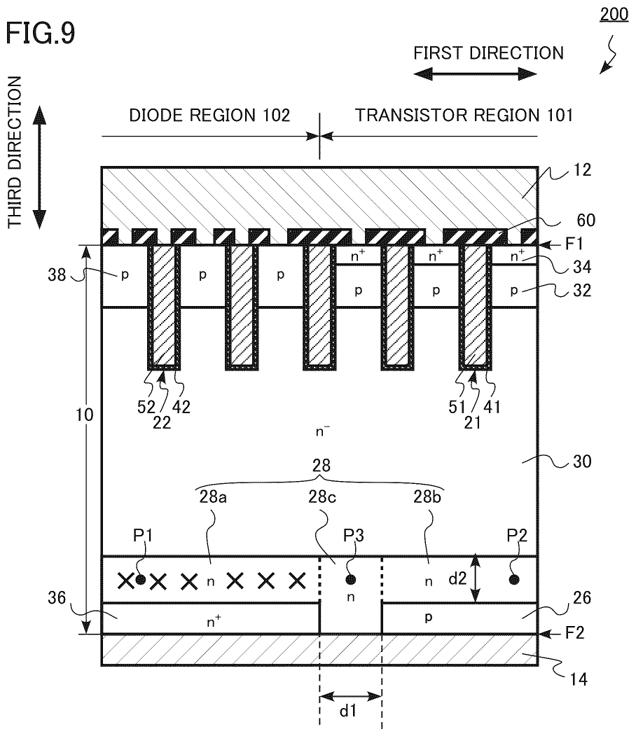

FIG. 9 is a schematic cross-sectional view of a part of the semiconductor device of the second embodiment. FIG. 9 is a view corresponding to FIG. 2 of the first embodiment.

The first buffer region 28 of the RC-IGBT 200 further includes a third region 28c in addition to the first region 28a and the second region 28b.

The third region 28c is provided between the contact region 36 and the collector region 26. The third region 28c is in contact with the second face F2.

The n-type impurity concentration of the first region 28 a is equal to or more than 80% and equal to or less than 120% of the n-type impurity concentration of the third region 28c. The n-type impurity concentration of the first region 28 a is, for example, equal to or more than 90% and equal to or less than 110% of the n-type impurity concentration of the third region 28c. The n-type impurity concentration of the first region 28a is, for example, substantially the same as the n-type impurity concentration of the third region 28c.

The carrier concentration of the first region 28a is lower than the carrier concentration of the third region 28c. The carrier concentration of the first region 28a is, for example, equal to or more than 1/1000 and equal to or less than ½ of the carrier concentration of the third region 28c. The carrier concentration of the third region 28c is higher than the carrier concentration of the first region 28a.

The n-type impurity concentration and the carrier concentration of the third region 28c are measured, for example, at a position of a third point P3 in FIG. 9. The distance in the third direction from the second face F2 to the first point P1 and the distance in the third direction from the second face F2 to the second point P2 are equal to a distance in the third direction from the second face F2 to the third point P3.

The third region 28c includes or does not include crystal defects. The crystal defect density of the third region 28c is, for example, lower than the crystal defect density of the first region 28a. The crystal defect density of the first region 28a is, for example, higher than the crystal defect density of the third region 28c.

The contact region 36 and the collector region 26 are separated in the first direction with the third region 28c interposed between the contact region 36 and the collector region 26. A distance (d1 in FIG. 9) in the first direction between the contact region 36 and the collector region 26 is, for example, equal to or more than a distance (d2 in FIG. 9) in the third direction between the collector region 26 and the drift region 30. The distance d1 in the first direction between the contact region 36 and the collector region 26 is, for example, equal to or less than 5 times the distance d2 in the third direction between the collector region 26 and the drift region 30.

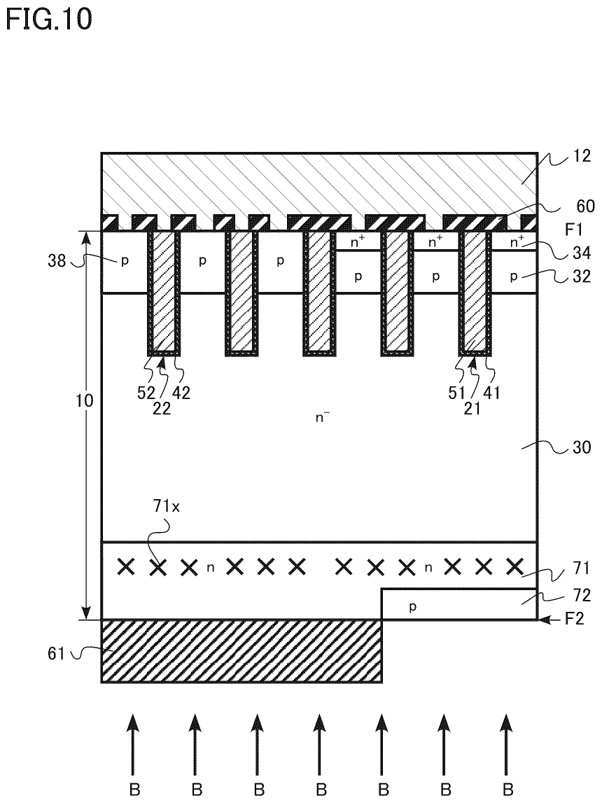

FIG. 10 is a schematic cross-sectional view illustrating an example of a method for manufacturing the semiconductor device of the second embodiment. FIG. 10 is a view corresponding to FIG. 5 of the method for manufacturing the semiconductor device of the first embodiment.

For example, before the second ion implantation is performed, the resist layer 61 is formed on a part of the second face F2. In the second ion implantation, p-type impurities are implanted into the semiconductor layer 10 from a side of the second face F2 using the resist layer 61 as a mask by using an ion implantation method. The p-type impurities are, for example, boron (B). The p-type region 72 is formed in a part of a space between the first n-type region 71 and the second face F2 by implantation of p-type impurities. The p-type region 72 finally becomes the collector region 26.

Then, the RC-IGBT 200 of the second embodiment illustrated in FIG. 9 can be manufactured by performing a manufacturing method similar to the method for manufacturing the semiconductor device of the first embodiment.

Next, the function and effect of the semiconductor device of the second embodiment will be described.

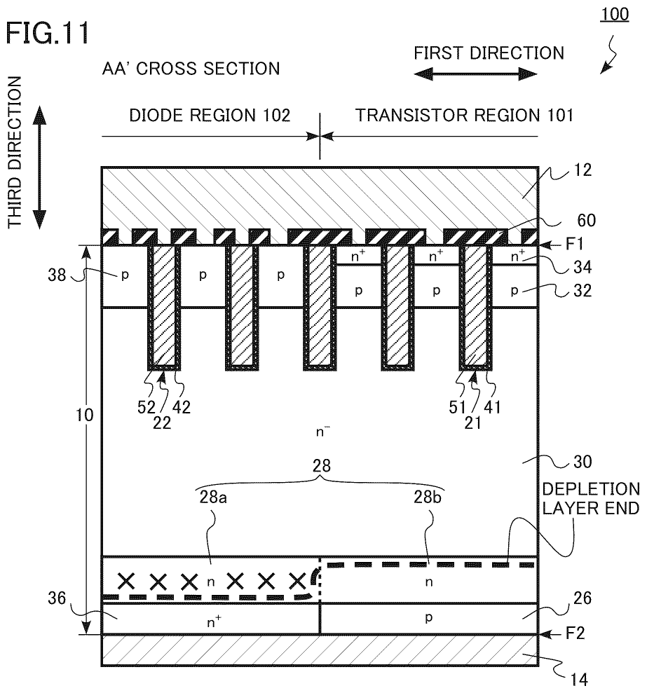

FIG. 11 is an explanatory diagram of the function of the semiconductor device of the second embodiment. FIG. 11 is a diagram illustrating a problem of the semiconductor device of the first embodiment. FIG. 11 is a view corresponding to FIG. 2 of the first embodiment.

FIG. 11 illustrates a state where the depletion layer extends to the drift region 30 when the RC-IGBT 100 is in an off-state. In FIG. 11, a depletion layer end is indicated by a dotted line.

The carrier concentration of the first region 28a of the first buffer region 28 of the diode region 102 is lower than the second region 28b of the first buffer region 28 of the transistor region 101. Therefore, the depletion layer easily extends in the first region 28a as compared with the second region 28b.

In this case, the distance between the depletion layer end in the first region 28a and the collector region 26 becomes short, and injection of holes from the collector region 26 into the depletion layer easily occurs. Therefore, leakage current at a high temperature may increase, and thermal runaway at a high temperature may occur.

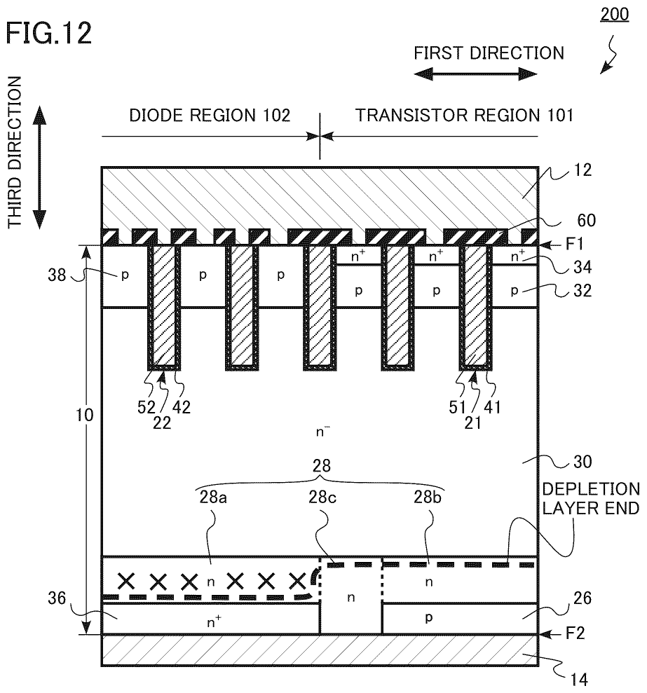

FIG. 12 is an explanatory diagram of the function and effect of the semiconductor device of the second embodiment. FIG. 12 is a view corresponding to FIG. 9 of the second embodiment.

FIG. 12 illustrates a state where the depletion layer extends to the drift region 30 when the RC-IGBT 200 is in an off-state. In FIG. 12, a depletion layer end is indicated by a dotted line.

In the RC-IGBT 200, the contact region 36 and the collector region 26 are separated in the first direction with the third region 28c interposed between the contact region 36 and the collector region 26. The carrier concentration of the third region 28c is higher than the carrier concentration of the first region 28a.

Therefore, as compared with the RC-IGBT 100, the distance between the depletion layer end in the first region 28a and the collector region 26 is increased. Therefore, injection of holes from the collector region 26 into the depletion layer is suppressed. Thus, leakage current at a high temperature is further suppressed, and thermal runaway at a high temperature is further suppressed.

From the viewpoint of suppressing injection of holes from the collector region 26 into the depletion layer, the distance d1 in the first direction between the contact region 36 and the collector region 26 is preferably equal to or less than the distance d2 in the third direction between the collector region 26 and the drift region 30.

### Modification

A semiconductor device of a modification of the second embodiment is different from the semiconductor device of the second embodiment in that the third region has a first portion in contact with the second face and a second portion between the first portion and the third semiconductor region, and a second conductivity type impurity concentration of the first portion is higher than a second conductivity type impurity concentration of the second portion.

The semiconductor device of the modification of the second embodiment is an RC-IGBT 210 in which an IGBT and a free wheeling diode are formed on the same semiconductor chip.

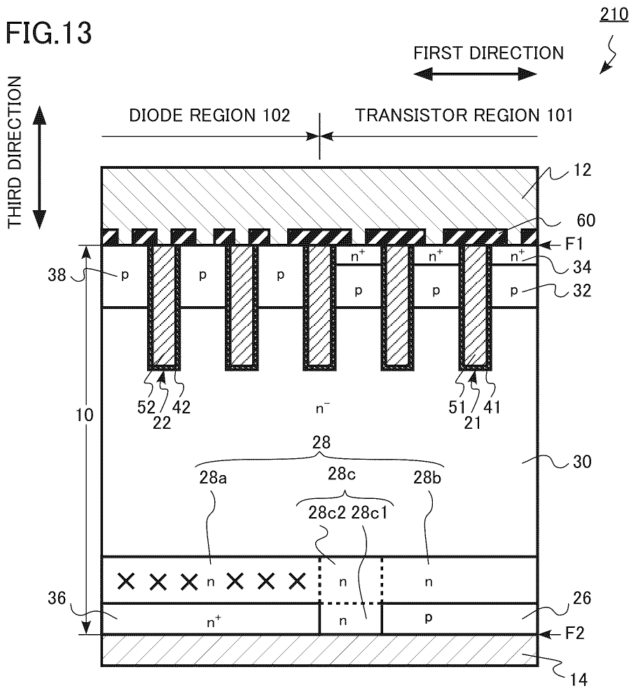

FIG. 13 is a schematic cross-sectional view of a part of the semiconductor device of the modification of the second embodiment. FIG. 13 is a view corresponding to FIG. 9 of the second embodiment.

In the first buffer region 28 of the RC-IGBT 210, the third region 28c includes a first portion 28c1 and a second portion 28c2.

The first portion 28c1 is in contact with the second face F2. The second portion 28c2 is provided between the first portion 28c1 and the drift region 30.

The n-type impurity concentration of the first portion 28c1 is higher than the n-type impurity concentration of the second portion 28c2. The n-type impurity concentration of the first portion 28c1 is higher than the n-type impurity concentration of the second region 28b.

In the RC-IGBT 210, since the first portion 28c1 having a high n-type impurity concentration is provided, the distance between the depletion layer end in the first region 28a and the collector region 26 is further increased. Thus, leakage current at a high temperature is further suppressed, and thermal runaway at a high temperature is further suppressed.

As described above, according to the second embodiment and the modification, a semiconductor device including an RC-IGBT having an IGBT and a diode and capable of improving characteristics by suppressing thermal runaway at a high temperature can be realized.

### Third Embodiment

A semiconductor device of a third embodiment is different from the semiconductor device of the second embodiment in that the semiconductor layer further includes an eighth semiconductor region of a second conductivity type provided between the second semiconductor region and the third semiconductor region, having a second conductivity type impurity concentration lower than a second conductivity type impurity concentration of the sixth semiconductor region, and having a second conductivity type impurity concentration higher than a second conductivity type impurity concentration of the third semiconductor region. Hereinafter, description of contents overlapping with the second embodiment may be partially omitted.

The semiconductor device of the third embodiment is an RC-IGBT 300 in which an IGBT and a free wheeling diode are formed on the same semiconductor chip.

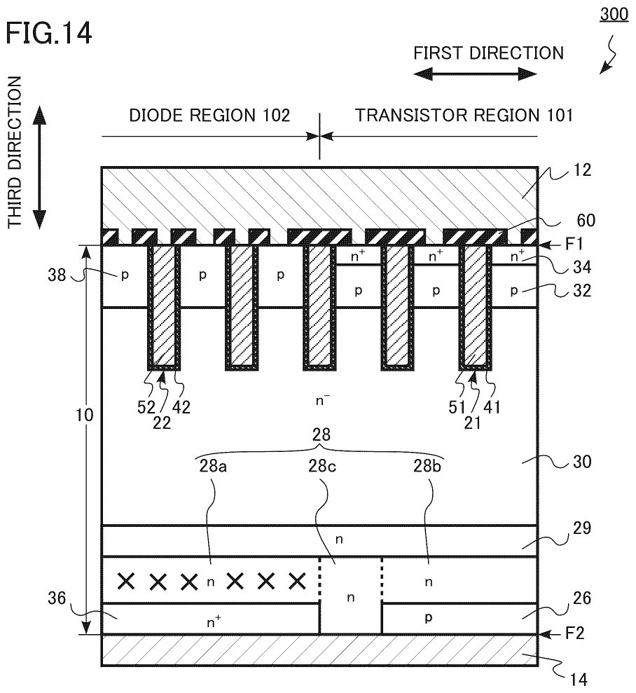

FIG. 14 is a schematic cross-sectional view of a part of the semiconductor device of the third embodiment. FIG. 14 is a view corresponding to FIG. 9 of the second embodiment.

In the RC-IGBT 300, the semiconductor layer 10 further includes an n-type second buffer region 29 (eighth semiconductor region).

The second buffer region 29 is an n-type semiconductor region. The second buffer region 29 is provided between the first buffer region 28 and the drift region 30.

The n-type impurity concentration of the second buffer region 29 is lower than the n-type impurity concentration of the contact region 36. The n-type impurity concentration of the second buffer region 29 is higher than the n-type impurity concentration of the drift region 30.

The carrier concentration of the second buffer region 29 is higher than the carrier concentration of the first region 28a of the first buffer region 28. The crystal defect density of the second buffer region 29 is lower than the crystal defect density of the first region 28a of the first buffer region 28.

In the formation of the second buffer region 29, for example, in the manufacturing method of the first embodiment, before the first ion implantation for forming the first n-type region 71 is performed, ion implantation of n-type impurities in which the n-type region is formed in a region closer to the first face F1 than the first n-type region 71 is performed. Then, the semiconductor layer 10 is irradiated with the infrared laser IR from a side of the second face F2 to activate n-type impurities in the n-type region and recover crystal defects.

In the RC-IGBT 300, by providing the second buffer region 29 having a high carrier concentration, it is possible to suppress the depletion layer extending from a side of the first face F1 from reaching defects in the first region 28a. Since only a weak electric field is applied to the defects, the generated current can be suppressed. On the other hand, during the operation of the diode, since the first region 28a contributes to the disappearance of the residual carriers, the trade-off relationship between the switching characteristics of the diode and the leakage current can be improved.

### Modification

A semiconductor device of a modification of the third embodiment is different from the semiconductor device of the third embodiment in that the second semiconductor region does not include the third region.

The semiconductor device of the modification of the third embodiment is an RC-IGBT 310 in which an IGBT and a free wheeling diode are formed on the same semiconductor chip.

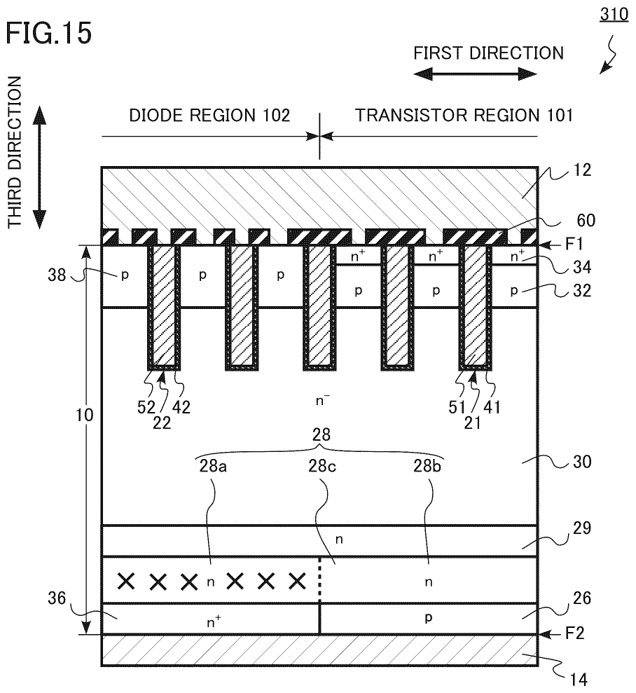

FIG. 15 is a schematic cross-sectional view of a part of the semiconductor device of the modification of the third embodiment. FIG. 15 is a view corresponding to FIG. 14 of the third embodiment.

The first buffer region 28 of the RC-IGBT 310 does not include the third region 28c. The contact region 36 and the collector region 26 are in contact with each other.

As described above, according to the third embodiment and the modification, a semiconductor device including an RC-IGBT having an IGBT and a diode and capable of improving characteristics by suppressing thermal runaway at a high temperature can be realized.

In the first to third embodiments, a case where the semiconductor layer is single crystal silicon has been described as an example, but the semiconductor layer is not limited to single crystal silicon. For example, other single crystal semiconductors such as single crystal silicon carbide may be used.

In the first to third embodiments, a case where the first conductivity type is p-type and the second conductivity type is n-type has been described as an example, but the first conductivity type may be n-type and the second conductivity type may be p-type.

In the first to third embodiments, the RC-IGBT having a trench-gate type IGBT has been described as an example, but an RC-IGBT having a planar gate type IGBT may be used.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a transistor region; and
a diode region, wherein
the transistor region includes:
a semiconductor layer having a first face and a second face opposed to the first face, the semiconductor layer including
a first semiconductor region of a first conductivity type in contact with the second face,
a second semiconductor region of a second conductivity type provided between the first semiconductor region and the first face,
a third semiconductor region of the second conductivity type provided between the second semiconductor region and the first face and having a second conductivity type impurity concentration lower than a second conductivity type impurity concentration of the second semiconductor region,
a fourth semiconductor region of the first conductivity type provided between the third semiconductor region and the first face, and
a fifth semiconductor region of the second conductivity type provided between the fourth semiconductor region and the first face and in contact with the first face;
a gate electrode opposed to the fourth semiconductor region;
a gate insulating film provided between the gate electrode and the fourth semiconductor region;
a first electrode in contact with the fifth semiconductor region; and
a second electrode in contact with the first semiconductor region,
the diode region includes:
the semiconductor layer including
the second semiconductor region,
the third semiconductor region,
a sixth semiconductor region of the second conductivity type provided between the second semiconductor region and the second face, in contact with the second face, and having a second conductivity type impurity concentration higher than the second conductivity type impurity concentration of the second semiconductor region, and
a seventh semiconductor region of the first conductivity type provided between the third semiconductor region and the first face and in contact with the first face;
the first electrode in contact with the seventh semiconductor region; and
the second electrode in contact with the sixth semiconductor region,
wherein the second semiconductor region includes a first region and a second region,
the first region is provided between the sixth semiconductor region and the third semiconductor region,
the second region is provided between the first semiconductor region and the third semiconductor region, and
a second conductivity type impurity concentration of the first region is equal to or more than 80% and equal to or less than 120% of a second conductivity type impurity concentration of the second region, and a carrier concentration of the first region is lower than a carrier concentration of the second region.

2. The semiconductor device according to claim 1, wherein a crystal defect density of the first region is higher than a crystal defect density of the second region.

3. The semiconductor device according to claim 1, wherein the second semiconductor region further includes a third region, and
the third region is in contact with the second face, the third region is provided between the sixth semiconductor region and the first semiconductor region, and the carrier concentration of the first region is lower than a carrier concentration of the third region.

4. The semiconductor device according to claim 3, wherein the third region has a first portion in contact with the second face and a second portion between the first portion and the third semiconductor region, and a second conductivity type impurity concentration of the first portion is higher than a second conductivity type impurity concentration of the second portion.

5. The semiconductor device according to claim 3, wherein the semiconductor layer further includes an eighth semiconductor region of a second conductivity type provided between the second semiconductor region and the third semiconductor region, having a second conductivity type impurity concentration lower than a second conductivity type impurity concentration of the sixth semiconductor region, and having a second conductivity type impurity concentration higher than a second conductivity type impurity concentration of the third semiconductor region.

6. The semiconductor device according to claim 1, wherein the semiconductor layer further includes an eighth semiconductor region of a second conductivity type provided between the second semiconductor region and the third semiconductor region, having a second conductivity type impurity concentration lower than a second conductivity type impurity concentration of the sixth semiconductor region, and having a second conductivity type impurity concentration higher than a second conductivity type impurity concentration of the third semiconductor region.

7. The semiconductor device according to claim 1, wherein the carrier concentration of the first region is equal to or less than ½ of the carrier concentration of the second region.

8. The semiconductor device according to claim 3, wherein a first distance in a first direction between the sixth semiconductor region and the first semiconductor region is equal to or more than a second distance in a third direction between the first semiconductor region and the third semiconductor region, the first direction being parallel to the first face and the third direction connecting the first face and the second face.

9. The semiconductor device according to claim 8, wherein the first distance is equal to or less than 5 times the second distance.

10. A semiconductor device comprising:
a transistor region; and
a diode region, wherein
the transistor region includes:
a semiconductor layer having a first face and a second face opposed to the first face, the semiconductor layer including
a first semiconductor region of a first conductivity type in contact with the second face,
a second semiconductor region of a second conductivity type provided between the first semiconductor region and the first face,
a third semiconductor region of the second conductivity type provided between the second semiconductor region and the first face and having a second conductivity type impurity concentration lower than a second conductivity type impurity concentration of the second semiconductor region,
a fourth semiconductor region of the first conductivity type provided between the third semiconductor region and the first face, and
a fifth semiconductor region of the second conductivity type provided between the fourth semiconductor region and the first face and in contact with the first face;
a gate electrode opposed to the fourth semiconductor region;
a gate insulating film provided between the gate electrode and the fourth semiconductor region;
a first electrode in contact with the fifth semiconductor region; and
a second electrode in contact with the first semiconductor region,
the diode region includes:
the semiconductor layer including
the second semiconductor region,
the third semiconductor region,
a sixth semiconductor region of the second conductivity type provided between the second semiconductor region and the second face, in contact with the second face, and having a second conductivity type impurity concentration higher than the second conductivity type impurity concentration of the second semiconductor region, and
a seventh semiconductor region of the first conductivity type provided between the third semiconductor region and the first face and in contact with the first face;
the first electrode in contact with the seventh semiconductor region; and
the second electrode in contact with the sixth semiconductor region,
wherein the second semiconductor region includes a first region and a second region,
the first region is provided between the sixth semiconductor region and the third semiconductor region,
the second region is provided between the first semiconductor region and the third semiconductor region, and
a carrier concentration of the first region is lower than a carrier concentration of the second region,
the second semiconductor region further includes a third region, and
the third region is in contact with the second face, the third region is provided between the sixth semiconductor region and the first semiconductor region, and the carrier concentration of the first region is lower than a carrier concentration of the third region.

11. The semiconductor device according to claim 10, wherein a crystal defect density of the first region is higher than a crystal defect density of the second region.

12. The semiconductor device according to claim 10, wherein the third region has a first portion in contact with the second face and a second portion between the first portion and the third semiconductor region, and a second conductivity type impurity concentration of the first portion is higher than a second conductivity type impurity concentration of the second portion.

13. The semiconductor device according to claim 10, wherein the semiconductor layer further includes an eighth semiconductor region of a second conductivity type provided between the second semiconductor region and the third semiconductor region, having a second conductivity type impurity concentration lower than a second conductivity type impurity concentration of the sixth semiconductor region, and having a second conductivity type impurity concentration higher than a second conductivity type impurity concentration of the third semiconductor region.

14. The semiconductor device according to claim 10, wherein the carrier concentration of the first region is equal to or less than ½ of the carrier concentration of the second region.

15. The semiconductor device according to claim 10, wherein a first distance in a first direction between the sixth semiconductor region and the first semiconductor region is equal to or more than a second distance in a third direction between the first semiconductor region and the third semiconductor region, the first direction being parallel to the first face and the third direction connecting the first face and the second face.

16. The semiconductor device according to claim 15, wherein the first distance is equal to or less than 5 times the second distance.
